(19) United States
(12) Patent Application Publication
(10) Pub. No.: US 2013/0243018 A1
(43) Pub. Date: Sep. 19, 2013

(54) GAIN MEDIUM WITH IMPROVED THERMAL CHARACTERISTICS

(71) Applicant: DAYLIGHT SOLUTIONS, INC., San Diego, CA (US)

(72) Inventor: David P. Caffey, San Diego, CA (US)

(73) Assignee: DAYLIGHT SOLUTIONS, INC., San Diego, CA (US)

(21) Appl. No.: 13/793,197

(22) Filed: Mar. 11, 2013

Related U.S. Application Data
(60) Provisional application No. 61/610,865, filed on Mar. 14, 2012.

(51) Int. Cl. H01S 5/024; H01S 5/02

(52) U.S. Cl. CPC H01S 5/024; H01S 5/02
USPC 372/36; 372/38.04

(57) ABSTRACT

A laser assembly (10) that generates a beam (20) includes a gain medium (12) having a first facet region (24) that includes a first facet (16), a second facet region (26) that includes a second facet (18), and an intermediate region (28) that separates and connects the facet regions (24) (26). Additionally, the gain medium (12) includes a substrate layer (30) and a core layer (34) that extend between the facets (16) (18). The gain medium (12) is designed so that when current is directed to the gain medium, (i) current flows through the core layer (34) in the intermediate region (28) to generate the beam (20), and (ii) current does not flow through or flows at a reduced rate through the core layer (34) in one or both facet regions (24) (26).

### RELATED INVENTION

This application claims priority on U.S. Provisional Application Ser. No. 61/610,865, filed Mar. 14, 2012 and entitled “GAIN MEDIUM WITH IMPROVED THERMAL CHARACTERISTICS”. As far as permitted, the contents of U.S. Provisional Application Ser. No. 61/610,865 are incorporated herein by reference.

### BACKGROUND

Lasers can be used for many things, including but not limited to testing, measuring, diagnostics, pollution monitoring, leak detection, security, pointer tracking, jamming a guidance system, analytical instruments, homeland security and industrial process control, and/or a free space communication system.

Recently, Quantum Cascade (“QC”) as well as Interband Cascade (IC) gain media have been used in applications that require a mid-infrared (“MIR”) output beam. Unfortunately, a significant amount of heat is generated by the operation of a QC or IC gain medium. Further, the core layers of a QC or IC gain medium typically have very low thermal conductivity. As a result thereof, the QC or IC gain medium can become very hot during operation. This can greatly reduce the operational life of the QC or IC gain medium.

### SUMMARY

A laser assembly that generates a beam when power is directed to the laser assembly includes a QC or IC gain medium having (i) a first facet region that includes a first facet, (ii) a second facet region that includes a second facet, and (iii) an intermediate region that separates the facet regions and connects the facet regions. Additionally, the gain medium includes a substrate layer and a core layer that extend between the facets. In one embodiment, the gain medium is designed so that when power is directed to the gain medium, (i) current flows through the core layer in the intermediate region to generate the beam, and (ii) current does not flow through the core layer in one or both facet regions. Current blocking can be achieved by making the core non-conductive or semi-insulating, and/or by making the upper and/or lower cladding layer non-conducting or semi-insulating. As a result of this design, the temperature of gain medium near one or both facets is reduced. This will reduce the likelihood of failure of the gain medium near one or both of the facets. In addition, higher operating temperature may be achieved for the intermediate region of the core, effectively leading to higher device temperature without exceeding the thermally induced temperature limit of approximately two hundred and twenty degrees Celsius (220 C).

In one embodiment, the gain medium includes a cladding layer that is adjacent to the core layer and that extends between the facets. Further, the cladding layer has a higher electrical conductivity in the intermediate region than in one or both of the facet regions.

In another embodiment, the gain medium includes an electrically conductive cladding layer that extends between the facets. In this embodiment, the cladding layer is electrically connected to the core layer in the intermediate region, and the cladding layer is electrically insulated from the core layer in one or both of the facet regions.

In alternative embodiment, the gain medium is designed so that when power is directed to the gain medium, (i) current flows through the core layer in the intermediate region at a first rate to generate the beam, and (ii) current flows through the core layer in the first facet region at a second rate that is less than the first rate. Further, the gain medium can be designed so that when power is directed to the gain medium, current flows through the core layer in the second facet region at a third rate that is less than the first rate.

The present invention is also directed to a method for generating a beam, and an assembly that includes the laser assembly.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is a simplified perspective view of a first embodiment of a laser assembly having features of the present invention;

FIG. 1B is a simplified cut-away view taken on line 1B-1B in FIG. 1A;

FIG. 1C is a simplified cut-away view taken on line 1C-1C in FIG. 1A;

FIG. 1D is a simplified cut-away view taken on line 1D-1D in FIG. 1A;

FIG. 2A is a simplified perspective view of another embodiment of a laser assembly having features of the present invention;

FIG. 2B is a simplified cut-away view taken on line 2B-2B in FIG. 2A;

FIG. 2C is a simplified cut-away view taken on line 2C-2C in FIG. 2A;

FIG. 2D is a simplified cut-away view taken on line 2D-2D in FIG. 2A;

FIG. 3A is a simplified perspective view of another embodiment of a laser assembly having features of the present invention;

FIG. 3B is a simplified cut-away view taken on line 3B-3B in FIG. 3A;

FIG. 3C is a simplified cut-away view taken on line 3C-3C in FIG. 3A;

FIG. 3D is a simplified cut-away view taken on line 3D-3D in FIG. 3A;

FIG. 4A is a simplified perspective view of another embodiment of a laser assembly having features of the present invention;

FIG. 4B is a simplified cut-away view taken on line 4B-4B in FIG. 4A;

FIG. 4C is a simplified cut-away view taken on line 4C-4C in FIG. 4A;

FIG. 4D is a simplified cut-away view taken on line 4D-4D in FIG. 4A;

FIG. 5 is a simplified top illustration of an assembly having features of the present invention;

FIG. 6 is a simplified side illustration of a gain medium and a heat sink having features of the present invention; and

FIG. 7 is a simplified end view of another embodiment of a laser assembly having features of the present invention.

### DESCRIPTION

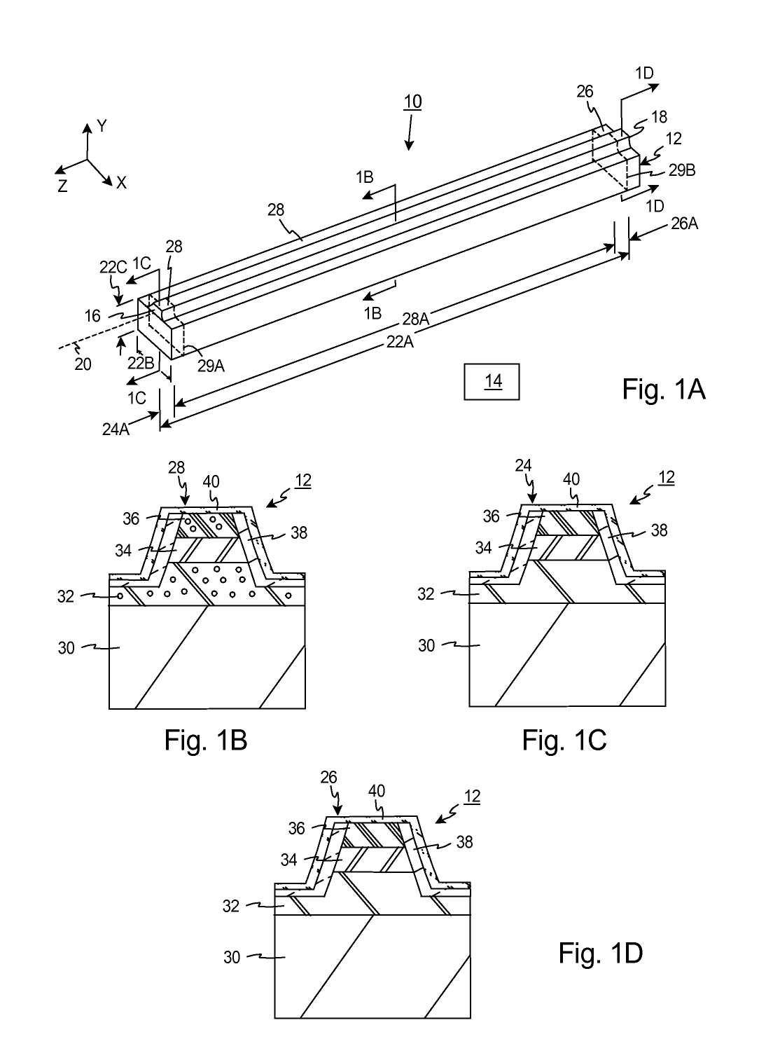

FIG. 1A is a simplified perspective view of a first embodiment of a laser assembly 10 that includes a gain medium 12 and a power source 14 that directs power to the gain medium 12. In one embodiment, the gain medium 12 includes a first end having a first facet 16, and a second end having a second facet 18 that is opposite to the first facet 16. Further, current from the power source 14 flowing through the gain medium 12 generates light that is emitted as an output beam 20 (illustrated as a dashed line) from one or both facets 16, 18.

As an overview, in certain embodiments, the gain medium 12 is a QC or IC gain medium and is uniquely designed so that when current is directed to the gain medium 12 from the power source 14, current flows through the gain medium 12 intermediate the facets 16, 18, but the current does not flow (or the current level (or the current density) is reduced relative to the center) through the gain medium 12 near one or both facets 16, 18. As a result thereof, the temperature of gain medium 12 near the one or both facets 16, 18 is reduced. This will reduce the likelihood of failure of the gain medium 12 near one or both of the facets 16, 18.

Some of the Figures provided herein include an orientation system that designates an X axis, a Y axis, and a Z axis. It should be understood that the orientation system is merely for reference and can be varied. Moreover, these axes can alternatively be referred to as a first, second, or third axis.

The laser assemblies 10 provided herein can be used in a variety of applications, such as testing, measuring, diagnostics, pollution monitoring, leak detection, security, pointer tracking, jamming a guidance system, analytical instruments, infrared microscopes, imaging systems, homeland security and industrial process control, and/or a free space communication system. It should be noted that this is a non-exclusive list of possible applications.

The power source 14 is electrically connected to and directs power to the gain medium 12. In one embodiment, the power source 14 directs current to the gain medium 12 in a pulsed fashion. Alternatively, the power source 14 can direct current to the gain medium 12 in a continuous fashion. The power source 414 can receive power from a generator (not shown), a battery (not shown), or another power source (not shown). The power source 14 can include one or more processors that are used to control the current flow to the gain medium 12.

In one embodiment, the gain medium 12 is a broadband emitter. Alternatively, both facets of the gain medium 12 can be coated with a reflective coating to form a Fabry-Perot laser. Still alternatively, the gain medium 12 can be tuned to adjust the primary wavelength of the output beam 20. For example, a wavelength selective element (not shown in FIG. 1A) can be incorporated into the gain medium 12. Alternatively, for example, the laser assembly 10 can include an external wavelength selective element (not shown in FIG. 1A) that allows the wavelength of the output beam 20 to be tuned.

In one embodiment, the gain medium 12 is a Quantum Cascade (“QC”) gain medium that generates an output beam 20 that is in the mid-infrared (“MIR”) range. In an alternative embodiment, the gain medium 12 can be an Interband Cascade (“IC”) gain media. An Interband Cascade gain medium is a hybrid between laser diodes having a direct bandgap and Quantum Cascade gain media.

In FIG. 1A, the output beam 20 only emits from the first facet 16. In this embodiment, the first facet 16 is coated with a reflective coating and the second facet 18 is coated with a highly reflective coating. With the reflective coating on the first facet 16, a portion of the light directed at the first facet 16 is reflected back into the gain medium 12 and a portion of the light directed at the first facet 16 is transmitted through the first facet 16. Further, with the highly reflective coating on the second facet 18, a bulk of the light directed at the second facet 18 is reflected back into the gain medium 12. Alternatively, the facets 16, 18 can be coated so that light emits from both facets 16, 18.

As a non-exclusive example, a suitable QC gain medium 12 can have (i) a length 22A (from the first facet 16 to the second facet 18) of between approximately 0.5 and six millimeters, (ii) a width 22B (along the slow axis) of approximately five hundred microns, and (iii) a height 22C (along the fast axis) of approximately one hundred and fifty microns. However, the gain medium 12 can have a size and shape different than this.

Further, as provided herein, the gain medium 12 can be separated into three continuous regions along the length direction, namely (i) a first facet region 24, (ii) a second facet region 26, and (ii) an intermediate region 28 that separates and connects the first facet region 24 from the second facet region 26. It should be noted that the gain medium 12 is physically not separated, however, (i) a first dashed line 29A is used to illustrate the transition of the first facet region 24 and the intermediate region 28; and (ii) a second dashed line 29B is used to illustrate the transition of the intermediate region 28 and the second facet region.

The first facet region 24 includes the first facet 16 and the area immediately near the first facet 16. Similarly, the second facet region 26 includes the second facet 18 and the area immediately near the second facet 18. Finally, the intermediate region 28 extends between and separates the first facet region 24 from the second facet region 26.

In one non-exclusive embodiment, (i) the first facet region 24 has a first length 24A of between approximately ten to fifty microns in length, (ii) the second region 26 has a second length 26A of between approximately ten to fifty microns in length; and (iii) the intermediate region 28 has an intermediate length 28A that makes up the remaining length of the gain medium 12. In alternative, non-exclusive embodiments, the intermediate length 28A is between approximately 0.5 to ten millimeters, and the first length 24A and the second length 26A is between approximately two to twenty-five microns. It is recognized that most embodiments of the current blocking layers will result in additional optical losses caused by absorption and scattering, and that these losses can be compensated by having sufficient gain path length in the intermediate region.

FIG. 1B is a simplified cut-away of the intermediate region 28 of the gain medium 12 taken on line 1B-1B in FIG. 1A near the center of the gain medium 12. FIG. 1C is a simplified cut-away view of the first facet region 24 of the gain medium 12 taken on line 1C-1C in FIG. 1A near the first facet 16. Further, FIG. 1D is a simplified cut-away view of the second facet region 26 of the gain medium 12 taken on line 1D-1D in FIG. 1A taken near the second facet 18.

In this embodiment, the gain medium 12 includes a number of layers, namely (i) a substrate layer 30, (ii) a first cladding layer 32, (iii) a core layer 34 (as referred to as the “active region”), (iv) a second cladding layer 36, (v) a dielectric layer 38, and (vi) a conductive layer 40. The thickness and shape of these layers can be varied to suit the design of the gain medium 12. Further, one or more of the layers can be optional.

It should be noted that in certain embodiments, each layer 30, 32, 34, 36, 38, 40 extends the length of the gain medium 12 between the ends. With this design, each layer 30, 32, 34, 36, 38, 40 can be separated into the first facet region 24, the second facet region 26 and the third facet region 28. Stated in another fashion, with this design, each facet region 24, 26, 28 includes a portion of each of the layers 30, 32, 34, 36, 38, 40.

In certain embodiments, the power source 14 (illustrated in FIG. 1A) is electrically connected to the conductive layer 40 and the substrate layer 30. With this design, current from the power source 14 directed to intermediate region 28 of the gain medium 12 causes current to flow through the core layer 34 and the generation of the output beam 20 (illustrated in FIG. 1A).

As an overview, as provided herein, during operation, the core layer 34 of a unipolar device, such as a QC gain medium 12 has a much higher temperature than the core layer of a diode laser. The higher temperature of the QC gain medium 12 is caused by the relatively lower power efficiency and poor thermal conductivity (Kcore˜1-5 W/m-K) of the core layer 34 of the QC gain medium 12. Thus, the current in the QC gain medium 12 generates quite a bit of heat.

The QC gain medium 12 generates light through sub-band transitions and these bands do not shrink much if at all due to temperature or current flow. In contrast, laser diodes have bandgaps that shrink when heated. This shrinkage results in the absorption of laser light which causes localized heating that further shrinks the bandgap and creates a runaway condition of self absorption and current flow along the facet. To restate, the current blocking layers in laser diodes prevent band shrinkage/bending, while for QC cores, the current blocking layers prevent the generation of excess heat through optical inefficiency of the QC core.

Thus, as provided herein, for a QC gain medium 12, the temperatures of the core layer 34 is much higher at each facet 16, 18, than in the area therebetween (the intermediate region 28) due the discontinuity of material beyond the core layer 34 (i.e. air) at the facets 16, 18.

Unfortunately, as provided herein, the higher temperature of the core layer 34 can result in the failure of the gain medium 12 near one or both of the facets 16, 18. For example, the high core temperature subjects the coatings of the facets 16, 18 (i) to high temperatures (e.g. approximately one hundred to two hundred and twenty (100-220) degrees Celsius) in a small region at the termination of the core layer 34 on the facets 16, 18, and (ii) to very large radial thermal gradients immediately outside of the core layer 34 due to radial heat spreading geometry. These conditions cause high stress on the coating, which can lead to temperature-induced absorption, delamination and degradation. This excess temperature can cause degradation of the facets 16, 18, even for uncoated facets 16, 18.

Further, in certain embodiments, the gain medium 12 includes a solder layer (not shown) that electrically connects the core layer 34 to the respective cladding layer 32, 36. As discussed above, with previous designs, as the core layer 34 is heated the facets 16, 18 become very hot. This can cause an Indium or other low temperature solder to be very close to the melting point. This can also cause solder pullback due to surface tension and for certain metallization schemes used on the chip. Additional heating by unwanted light impingement on the substrate layer 30, the core layer 34, or solder layer can raise the solder temperature above the melting point. The molten solder can then flow out over the respective facet 16, 18, leading to a short.

The present invention teaches a way to inhibit the failure of the gain medium 12 near one or both facets 16, 18. This will enhance the lifespan and durability of the gain medium 12. Removing the facet temperature limit will also allow the gain medium to operate at a higher temperature while still maintaining reliability.

The substrate layer 30 is the typically the thickest part of the gain medium 12 and, as non-exclusive examples, can be made of n-doped indium phosphide (“InP”) or gallium antimonide (“GaSb”). In FIGS. 1B-1D, the substrate layer 30 is at the bottom, is generally rectangular shaped, and can have a thickness of between approximately 100 and 200 microns.

The first cladding layer 32 is positioned between the substrate layer 30 and the core layer 34, and the second cladding layer 36 is positioned on the top of the core layer 34. With this design, the core layer 34 is positioned between the first cladding layer 32 and the second cladding layer 36. The cladding layers 32, 36 have a lower refractive index than the core layer 34. As a result thereof, the cladding layers 32, 36 refract light back into the core layer 34 and act as a waveguide. In one embodiment, each cladding layer 32, 36, or portions thereof, can be made from n-doped InP. In certain embodiments, the InP material surrounding the core layer 34 has a relatively high coefficient of thermal conductivity (approximately ˜60 W/m/K). This will help to spread heat from the core layer 34. This also leads to large temperature gradients of micrometer scale radially about the core layer 34.

The core layer 34 is the active region of the gain medium 12, defines the two facets 16, 18, and includes a periodic series of thin layers of varying material composition forming a superlattice. The superlattice introduces a varying electric potential across the core layer 34 meaning that there is a varying probability of electrons occupying different positions over the length of the device. By suitable design of the layer thicknesses of the core layer 34, it is possible to engineer a population inversion between two subbands in the system which is required in order to achieve laser emission. Since the position of the energy levels in the system is primarily determined by the layer thicknesses and not the material, it is possible to tune the emission wavelength of core layer 34 over a wide range in the same material system.

In one embodiment, for a QC gain medium 12, the core layer 34 is a QC core layer that can utilize two different semiconductor materials, such as Indium gallium arsenide (“InGaAs”) and Aluminium indium arsenide (“AlInAs”) to form a series of potential wells and barriers for electron transitions. The output wavelength of the gain medium 12 can be changed by changing the thicknesses of the periodic layers. In one non-exclusive embodiment, the core layer 34 has a thickness of between approximately one to two microns. As mentioned above, the core layer 34 of a QC gain medium 12 typically has a very low thermal conductivity, approximately one to five W/m/K. This leads to high operating temperature of the core layer 34, which leads to reduced lifetime.

In another embodiment, for an IC gain medium, the core layer 34 is an IC core layer that can utilize Gallium Antimonide (GaSb), Aluminum Indium Arsenide (AlInAs), Gallium Indium Arsenide (GaInAs), Indium Arsenide (InAs), and Aluminum Antimonide (AlSb).

In the embodiment illustrated in FIGS. 1B-1D, the dielectric layer 38 is deposited on the sides of the core layer 34 to guide the current injected into the core layer 34 and guide the light generated by the core layer 34 to the facets 16, 18. The dielectric layer 38 can also be referred to as an undoped or semi-insulating cladding layer and can be made of Indium Phosphide (InP).

The conductive layer 40 coats the second cladding layer 36 and the dielectric layer 38 and provides an electrical contact for the power source 14. Further, the conductive layer 40 assists in removing heat created when producing light.

The power source 14 directs current to the gain medium 12 to force current through the core layer 34. As provided herein, in certain embodiments, the gain medium 12 is uniquely designed to inhibit current from reaching the core layer 34 in each facet region 24, 26 (at or near the facets 16, 18). Stated in another fashion, in certain embodiments, the gain medium 12 is uniquely designed so that when the power source 14 directs current to the gain medium 12, (i) current flows through the gain medium 12 in the intermediate region 28 (between the facets 16, 18), and (ii) current does not flow through the gain medium 12 in one or both facet regions 24, 26 (near one or both facets 16, 18). This will greatly reduce the temperatures in each facet region 24, 26 (at or near the facets 16, 18) in which current does not flow in, and this will reduce thermal and physical stress on the coatings on the facets 16, 18. This will also reduce the likelihood of failure of one or both of the facets 16, 18.

In certain embodiments, the relatively low thermal conductivity (Kcore˜1-5 W/m/K) of the core layer 34 means that current blocking is only required for a short distance from each facet 16, 18 to result in a significant reduction in temperature at each facet 16, 18. Further, a QC gain medium 12 has a relatively low cold-cavity optical self-absorption at the lasing wavelength. Thus, the laser light generated in the actively pumped intermediate region 28 of the core layer 34 can pass through unpumped facet regions 24, 26 with only small optical absorption and associated heating. Typical waveguide losses are on the order of 1-5 cm-1.

The method used to inhibit the flow of current or reduce the level of current through the core layer 34 in the facet regions 24, 26 can vary. For example, in the embodiment illustrated in FIGS. 1A-1D, (i) in the intermediate region 28, both of the cladding layers 32, 34 are electrically conductive; and (ii) in one or both of the facet regions 24, 26, one or both of the cladding layers 32, 34 are electrically non-conductive (fully or partly insulating). With this design, current flows through the core layer 34 in the intermediate region 28 to generate the beam 20, and current does not flow through the core layer 34 in one or both facet regions 16, 18.

In one embodiment, for example, (i) in the intermediate region 28, both of the cladding layers 32, 34 can be made of a doped (illustrated with circles) InP; and (ii) in one or both of the facet regions 24, 26, one or both of the cladding layers 32, 34 can be made of undoped or semi-insulating InP. With this design, one or both of the cladding layers 32, 34 have a higher electrical conductivity in the intermediate region 28 than in one or both of the facet regions 24, 26. In one embodiment, one or both of the cladding layers 32, 34 are electrical conductive in the intermediate region 28, and are non-conductive in one or both of the facet regions 24, 26.

In FIGS. 1C and 1D, current blocking in the facet regions 24, 26 is occurring in each of the cladding layers 32, 34. However, it should be noted that in this embodiment, current blocking in only one of the cladding layers 32, 34 in the facet regions 24, 26 will inhibit the flow of current near the respective facet 16, 18.

It should be noted that the core layer 34 can be mounted in an epi up or an epi down mounting configuration.

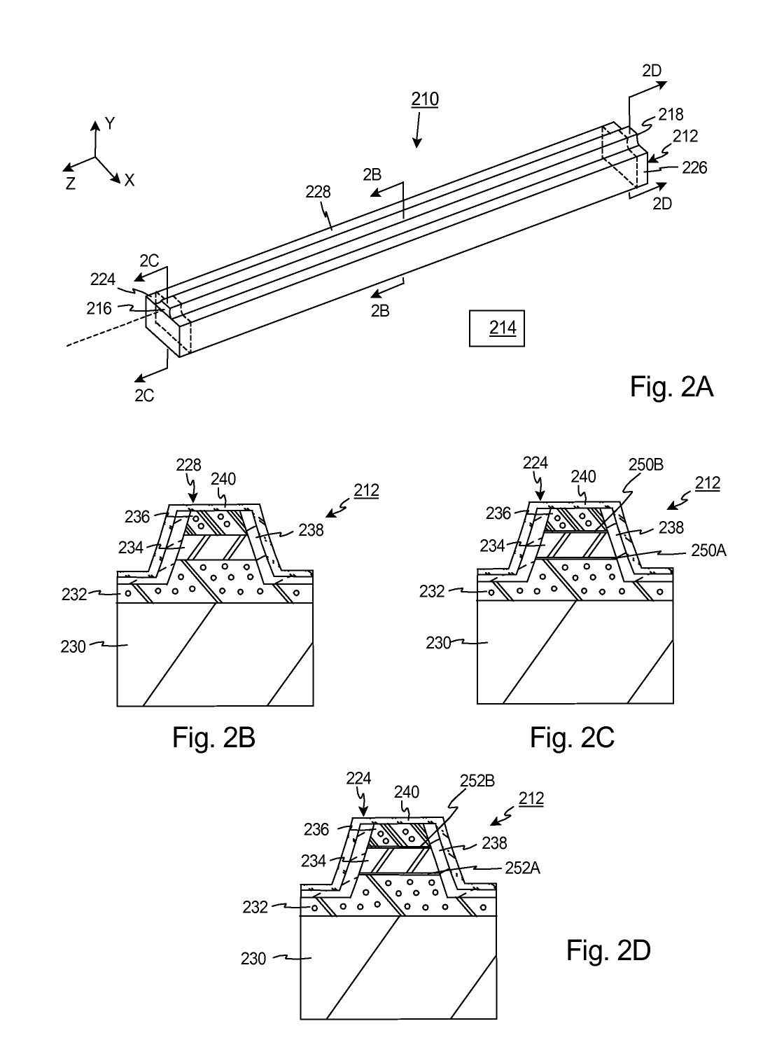

FIG. 2A is a simplified perspective view of another embodiment of a laser assembly 210 that includes a gain medium 212 and a power source 214 that are somewhat similar to the corresponding components described above. In this embodiment, the gain medium 212 is again uniquely designed so that when current is directed to the gain medium 212 from the power source 214, current flows through the gain medium 212 intermediate the facets 216, 218, but the current does not flow through the gain medium 212 near one or both facets 216, 218. The gain medium 212 is again divided into (i) the first facet region 224, (ii) the second facet region 226, and (iii) the intermediate region 228 which are similar in length to the corresponding regions described above.

FIG. 2B is a simplified cut-away of the intermediate region 228 taken on line 2B-2B in FIG. 2A near the center of the gain medium 212. FIG. 2C is a simplified cut-away view of the first facet region 224 taken on line 2C-2C in FIG. 2A near the first facet 216. Further, FIG. 2D is a simplified cut-away view of the second facet region 226 taken on line 2D-2D in FIG. 2A taken near the second facet 218.

In this embodiment, the gain medium 212 again includes (i) the substrate layer 230, (ii) the first cladding layer 232, (iii) the core layer 234, (iv) the second cladding layer 236, (v) the dielectric layer 238, and (vi) the conductive layer 240 that are somewhat similar to the corresponding components described above. However, in this embodiment, the entire first cladding layer 232 and the entire second cladding layer 234 are made of a conductive material such as doped (illustrated with circles) InP.

Further, in this embodiment, gain medium 212 includes (i) a lower first current blocker 250A (insulator) positioned between the core layer 234 and the first cladding layer 232 in the first facet region 224; (ii) an upper first current blocker 250B (insulator) positioned between the core layer 234 and the second cladding layer 236 in the first facet region 224; (iii) a lower second current blocker 252A (insulator) positioned between the core layer 234 and the first cladding layer 232 in the second facet region 226; and (iv) an upper second current blocker 252B (insulator) positioned between the core layer 234 and the second cladding layer 236 in the second facet region 226. In this embodiment, each blocker 250A-252B can be made of a partly or fully electrically insulating material. With this design, the current blocking layer is deposited directly on the core layer 234.

In this embodiment, each cladding layer 232, 236 is electrically connected and adjacent to the core layer 234 in the intermediate region 228. Further, each cladding layer 232, 236 is electrically insulated (or partly insulated) and spaced apart from the core layer 234 in each facet region 224, 226.

It should be noted that a single blocker (either upper or lower) can be used to block current near facet 216, 218. Further, each blocker 250A, 250B, 252A, 252B can be designed to be a partial insulator that allows for a reduced current flow through each facet region 224, 226.

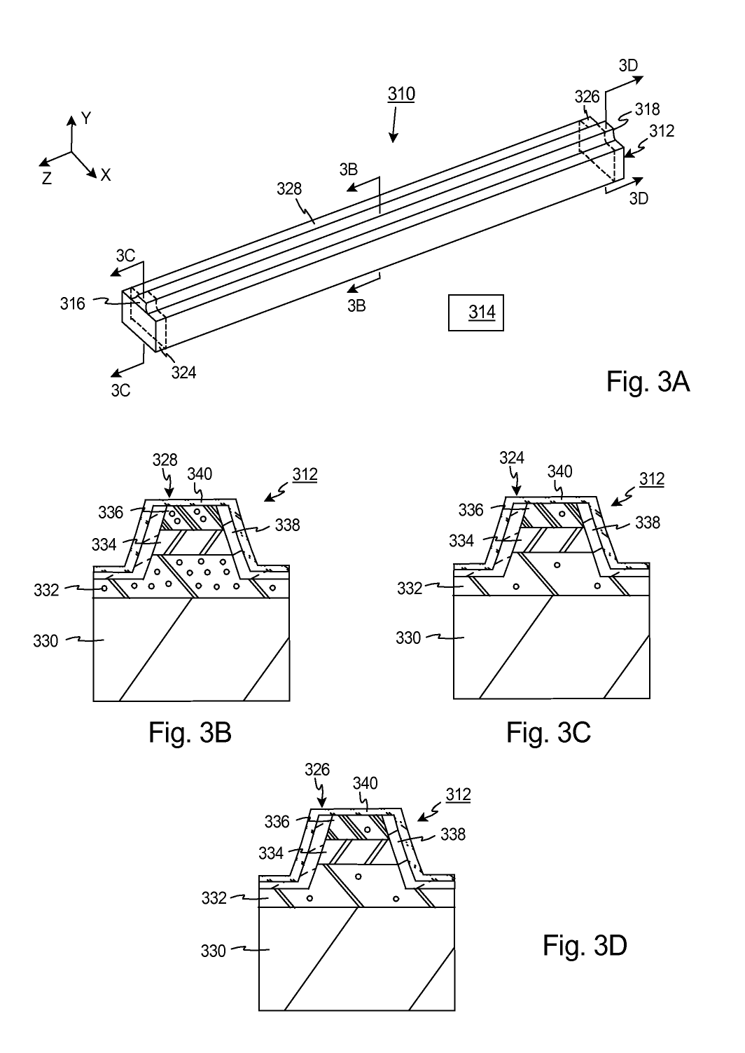

FIG. 3A is a simplified perspective view of another embodiment of a laser assembly 310 that includes a gain medium 312 and a power source 314 that are somewhat similar to the corresponding components described above. In this embodiment, the gain medium 312 is designed so that when current is directed to the gain medium 312 from the power source 314, the bulk of the current flows through and there is a higher current density in the gain medium 312 intermediate the facets 316, 318, and a reduced amount of current flows through and there is a lower current density in the gain medium 312 near one or both facets 316, 318. The gain medium 312 is again divided into (i) the first facet region 324, (ii) the second facet region 326, and (iii) the intermediate region 328 which are similar in length to the corresponding regions described above.

FIG. 3B is a simplified cut-away of the intermediate region 328 taken on line 3B-3B in FIG. 3A near the center of the gain medium 312. FIG. 3C is a simplified cut-away view of the first facet region 324 taken on line 3C-3C in FIG. 3A near the first facet 316. Further, FIG. 3D is a simplified cut-away view of the second facet region 326 taken on line 3D-3D in FIG. 3A taken near the second facet 318.

In this embodiment, the gain medium 312 again includes (i) the substrate layer 330, (ii) the first cladding layer 332, (iii) the core layer 334, (iv) the second cladding layer 336, (v) the dielectric layer 338, and (vi) the conductive layer 340 that are somewhat similar to the corresponding components described above.

However, in FIGS. 3A-3D, (i) in the intermediate region 328, both of the cladding layers 332, 334 are electrically conductive; and (ii) in one or both of the facet regions 324, 326, both of the cladding layers 332, 334 are semi-insulating or non-conductive. For example, (i) in the intermediate region 328, both of the cladding layers 332, 334 can be made of a doped (illustrated with circles) InP; and (ii) in one or both of the facet regions 324, 326, both of the cladding layers 332, 334 are made of partly doped InP (illustrated with fewer circles than in the intermediate region 328. The amount of current restriction in each facet regions 324, 326 can be varied to achieve the design requirements of the gain medium 312. For example, providing sufficient voltage and current to achieve optical transparency in regions 324, 326 can result in reduced optical self-absorption and associated heating while minimizing heating associated with typical operating current density in the intermediate region 328.

With this design, in alternative, non-exclusive embodiments, when current is directed to the gain medium 312, the current flow in each facet region 324, 326 is at least approximately 40, 50, 60, 70, 80, 90, 95 or 100 percent less than the current flow in the intermediate region 328. Stated in another fashion, with this design, the current flow in each facet regions 324, 326 is reduced when compared to the intermediate region 328.

Stated in yet another way, the gain medium 312 is designed so that when current is directed to the gain medium 312, (i) the current density in the core layer 334 of the intermediate region 328 is at a first current density, (ii) the current density in the core layer 334 of the first facet region 324 at a second rate that is less than the first current density, and (iii) the current density in the core layer 334 of the second facet region 326 at a third current density that is less than the first current density. With this design, in alternative, non-exclusive embodiments, when current is directed to the gain medium 312, the first current density is at least approximately 40, 50, 60, 70, 80, 90, or 100 percent greater than the second current density and the third current density.

In this embodiment, each cladding layers 32, 34 has a higher electrical conductivity in the intermediate region 28 than in each of the facet regions 24, 26. As alternative, non-exclusive examples, one or both of the cladding layers 32, 34 have an electrical conductivity in the intermediate region 28 that is at least approximately 50, 100, 200, or 300 percent greater than in one or both facet regions 24, 26.

It should be noted that the current flow in one or both facet regions can be reduced or completely blocked in number of other, non-exclusive fashions. For example, modifications (e.g. diffusion-induced disordering) can be done to reduce the conductivity of the core layer in the facet regions while maintaining the conductivity in the intermediate region.

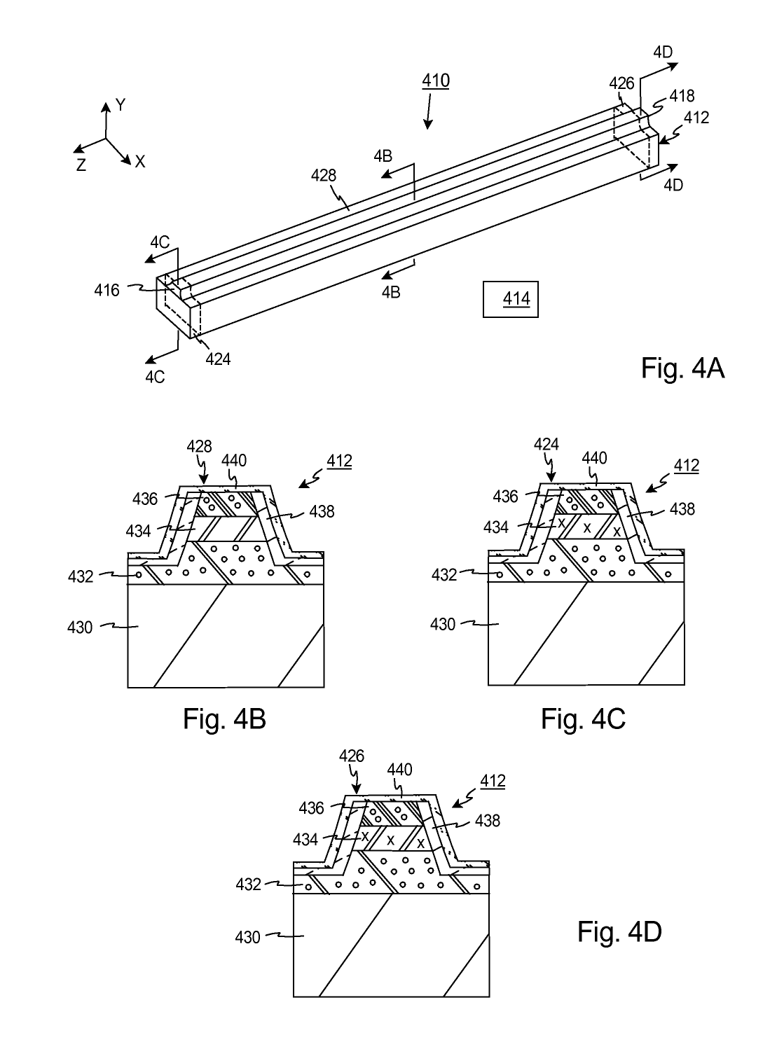

FIG. 4A is a simplified perspective view of another embodiment of a laser assembly 410 that includes a gain medium 412 and a power source 414 that are somewhat similar to the corresponding components described above. In this embodiment, the gain medium 412 is designed so that when current is directed to the gain medium 412 from the power source 414, the bulk of the current flows through (and there is a higher current density in) the gain medium 412 intermediate the facets 416, 418, and a reduced amount of current flows through (and there is a lower current density in) the gain medium 412 near one or both facets 416, 418. The gain medium 412 is again divided into (i) the first facet region 424, (ii) the second facet region 426, and (iii) the intermediate region 428 which are similar in length to the corresponding regions described above.

FIG. 4B is a simplified cut-away of the intermediate region 428 taken on line 4B-4B in FIG. 4A near the center of the gain medium 412. FIG. 4C is a simplified cut-away view of the first facet region 424 taken on line 4C-4C in FIG. 4A near the first facet 416. Further, FIG. 4D is a simplified cut-away view of the second facet region 426 taken on line 4D-4D in FIG. 4A taken near the second facet 418.

In this embodiment, the gain medium 412 again includes (i) the substrate layer 430, (ii) the first cladding layer 432, (iii) the core layer 434, (iv) the second cladding layer 436, (v) the dielectric layer 438, and (vi) the conductive layer 440 that are somewhat similar to the corresponding components described above. However, in FIGS. 4A-4D, (i) in the intermediate region 428, the core 434 is electrically conductive; and (ii) in one or both of the facet regions 424, 426, the core 434 is only partly conductive or is non-conductive (illustrated with x's). With this design, in alternative, non-exclusive embodiments, when current is directed to the gain medium 412, the current flow in each facet region 424, 426 is at least approximately 40, 50, 60, 70, 80, 90, 95 or 100 percent less than the current flow in the intermediate region 428.

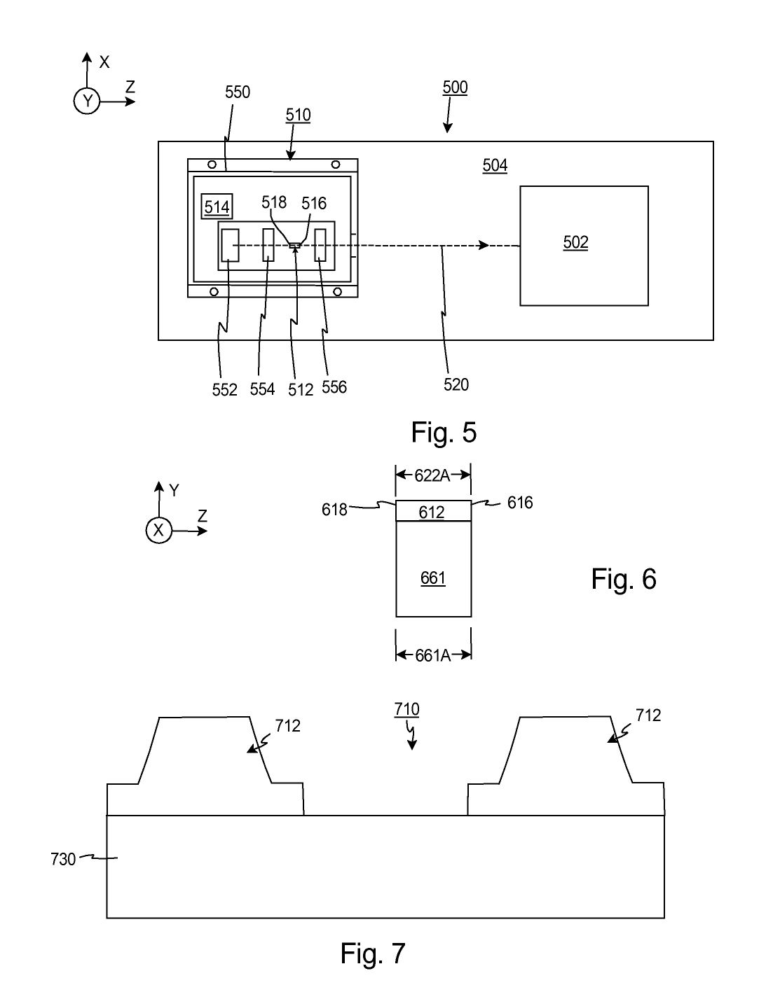

FIG. 5 is a simplified side view of an assembly 600 that includes a laser assembly 510 that generates an output beam 520, an object 502 that receives the output beam 520, and a rigid mounting base 504 that fixedly retains the laser assembly 510 and the object 502. In this embodiment, the laser assembly 510 is an external cavity laser and the major components include a gain medium 512, a power source 514, a laser housing 550, a wavelength dependent (“WD”) feedback assembly 552 that can be used to tune the primary wavelength of the output beam 520, a cavity lens 554, an output lens 556, and a control system 558 that directs the current to the gain medium 512. The power source 514 can be a generator (not shown), a battery (not shown), or another power source (not shown).

The gain medium 512 can be similar to any of the gain mediums 12, 212, 312, 412 described above. In FIG. 5, the gain medium 512 emits from both facets 516, 518. In this embodiment, (i) the second facet 518 that faces the cavity lens 554 and the WD feedback assembly 552, and (ii) the first facet 516 faces the output lens 556. In this embodiment, the second facet 518 is coated with an anti-reflection (“AR”) coating and the first facet 516 is coated with a reflective coating.

The laser housing 550 houses, encloses, and/or retains many of the components of the laser assembly 510. In FIG. 5, the laser housing 550 encloses and retains the gain medium 512, the output lens 556, the cavity lens 554, and the WD feedback assembly 552. The laser housing 550 can include a removable top that is not shown so that the components within the laser housing 550 are visible.

The WD feedback assembly 552 reflects light back to the gain medium 512 along the lasing axis, and is used to precisely adjust the lasing frequency of the external cavity and the wavelength of the output beam 520. The design of the WD feedback assembly 552 can vary pursuant to the teachings provided herein. Non-exclusive examples of suitable designs include a diffraction grating, a MEMS grating, prism pairs, a thin film filter stack with a redirector, an acoustic optic modulator, or an electro-optic modulator. The WD feedback assembly 452 can be fixed or adjustable (e.g. a motor that moves a grating).

The cavity lens 554 is positioned between the gain medium 512 and the WD feedback assembly 552 along the lasing axis (e.g., along the Z axis), and collimates and focuses the light that passes between these components. For example, in one embodiment, the cavity lens 554 can include an aspherical lens having an optical axis that is aligned with the lasing axis.

The output lens 556 collimates and focuses the light that exits the first facet 516 of the gain medium 512. For example, the output lens 556 can be somewhat similar in design to the cavity lens 554.

The gain medium 512 can generate quite a bit of heat. Accordingly, in certain embodiments, the laser assembly 510 can include a temperature controller (not shown) that transfers the heat away from the gain medium 512 to control the temperature of the gain medium 512. For example, the temperature controller can include one or more thermoelectric coolers (“TEC”) that transfer the heat from the gain medium 512.

FIG. 6 is a simplified side illustration of the gain medium 612 and a heat sink 661. In certain embodiment, the gain medium 612 fixedly secured to and positioned directly on the heat sink 661. Further, the heat sink 661 secures the gain medium 612 to the rigid mounting base 604 (illustrated in FIG. 5). In certain embodiments, the heat sink 661 can be made of a material having a high thermal conductivity so that the heat sink 661 readily transfers heat from the gain medium 612 to the mounting base 504. In certain embodiments, the heat sink 661 has a thermal conductivity of at least approximately 500-2000 W/mK, and preferably in the range of approximately 1500-2000 W/mK.

In this embodiment, the gain medium 612 has a gain medium length 622A (measured from the first facet 616 to the second facet 618) that is approximately equal to a heat sink length 661A of the heat sink 661 (measured on the lasing axis). With this design, the gain medium 612 can be designed to emit from both facets 616, 618 without the influence from the heat sink 661.

FIG. 7 is a simplified end view of another embodiment of the laser assembly 710. In this embodiment, multiple gain media 712 (only two are illustrated in FIG. 7) are positioned on a common substrate layer 730. The gain media 712 can be similar to any of the gain mediums 12, 212, 312, 412 described above.

While a number of exemplary aspects and embodiments of a laser assembly 10 have been discussed above, those of skill in the art will recognize certain modifications, permutations, additions and sub-combinations thereof. It is therefore intended that any claims that may be hereafter introduced with regard to the present invention are interpreted to include all such modifications, permutations, additions and sub-combinations as are within their true spirit and scope.

What is claimed is:

1. A laser assembly that generates a beam when current is directed to the laser assembly, the laser assembly comprising:
a gain medium including (i) a first facet region that includes a first facet, (ii) a second facet region that includes a second facet, and (iii) an intermediate region that separates the facet regions and connects the facet regions; the gain medium having a substrate layer, and a core layer that extends between the facets; wherein the gain medium is designed so that when current is directed to the gain medium, current flows through the core layer in the intermediate region to generate the beam, and current does not flow through the core layer in the first facet region; wherein the gain medium is one of a Quantum Cascade gain medium and an Interband Cascade gain medium.

2. The laser assembly of claim 1 wherein the gain medium is designed so that when current is directed to the gain medium, current does not flow through the core layer in second facet region.

3. The laser assembly of claim 2 wherein the gain medium includes a cladding layer that is adjacent to the core layer and that extends between the facets, wherein the cladding layer has a higher electrical conductivity in the intermediate region than in the facet regions.

4. The laser assembly of claim 2 wherein the gain medium includes an electrically conductive cladding layer that extends between the facets, wherein the cladding layer is electrically connected to the core layer in the intermediate region, and wherein the cladding layer is electrically insulated from the core layer in the facet regions.

5. The laser assembly of claim 1 wherein the gain medium includes a cladding layer that is adjacent to the core layer and that extends between the facets, wherein the cladding layer has a higher electrical conductivity in the intermediate region than in the first facet region.

6. The laser assembly of claim 1 wherein the gain medium includes an electrically conductive cladding layer that extends between the facets, wherein the cladding layer is electrically connected to the core layer in the intermediate region, and wherein the cladding layer is electrically insulated from the core layer in the first facet region.

7. The laser assembly of claim 1 wherein the gain medium is positioned on a heat sink and wherein the gain medium has a gain medium length that is approximately equal to a heat sink length of the heat sink.

8. A laser assembly that generates a beam when power is directed to the laser assembly, the laser assembly comprising:
a gain medium including (i) a first facet region that includes a first facet, (ii) a second facet region that includes a second facet, and (iii) an intermediate region that separates the facet regions and connects the facet regions; the gain medium having a substrate layer, and a core layer that extends between the facets; wherein the gain medium is designed so that when power is directed to the gain medium, current flows through the core layer in the intermediate region at a first rate to generate the beam, and current flows through the core layer in the first facet region at a second rate that is less than the first rate; wherein the gain medium is one of a Quantum Cascade gain medium and an Interband Cascade gain medium.

9. The laser assembly of claim 8 wherein the gain medium is designed so that when current is directed to the gain medium, current flows through the core layer in the second facet region at a third rate that is less than the first rate.

10. The laser assembly of claim 9 wherein the gain medium includes a cladding layer that is adjacent to the core layer and that extends between the facets, wherein the cladding layer has a higher electrical conductivity in the intermediate region than in the facet regions.

11. The laser assembly of claim 9 wherein the gain medium includes an electrically conductive cladding layer that extends between the facets, wherein the cladding layer is electrically connected to the core layer in the intermediate region, and wherein the cladding layer is partly electrically insulated from the core layer in the facet regions.

12. The laser assembly of claim 8 wherein the gain medium includes a cladding layer that is adjacent to the core layer and that extends between the facets, wherein the cladding layer has a higher electrical conductivity in the intermediate region than in the first facet region.

13. The laser assembly of claim 8 wherein the gain medium includes an electrically conductive cladding layer that extends between the facets, wherein the cladding layer is electrically connected to the core layer in the intermediate region, and wherein the cladding layer is partly electrically insulated from the core layer in the first facet region.

14. The laser assembly of claim 8 wherein the gain medium is positioned on a heat sink and wherein the gain medium has a gain medium length that is approximately equal to a heat sink length of the heat sink.

15. The laser assembly of claim 8 further comprising a WD feedback assembly reflects light back to the gain medium.

16. A method for generates a beam, the method comprising the steps of:
providing a power source of electrical power; and
providing a gain medium that includes (i) a first facet region having a first facet, (ii) a second facet region having a second facet, and (iii) an intermediate region that separates the facet regions and connects the facet regions; the gain medium having a substrate layer, and a core layer that extends between the facets; wherein the gain medium is designed so that when power is directed to the gain medium, current flows through the core layer in the intermediate region at a first rate to generate the beam, and current flows through the core layer in the first facet region at a second rate that is less than the first rate; wherein the gain medium is one of a Quantum Cascade gain medium and an Interband Cascade gain medium.

17. The method of claim 16 wherein the step of providing the gain medium includes the gain medium being designed so that when current is directed to the gain medium, current flows through the core layer in the second facet region at a third rate that is less than the first rate.

18. The method of claim 16 wherein the step of providing the gain medium includes the gain medium having a cladding layer that is adjacent to the core layer and that extends between the facets, wherein the cladding layer has a higher electrical conductivity in the intermediate region than in the facet regions.

19. The method of claim 16 wherein the step of providing the gain medium includes the gain medium having an electrically conductive cladding layer that extends between the facets, wherein the cladding layer is electrically connected to the core layer in the intermediate region, and wherein the cladding layer is partly electrically insulated from the core layer in the facet regions.

20. The method of claim 16 wherein the step of providing the gain medium includes the gain medium having a cladding layer that is adjacent to the core layer and that extends between the facets, wherein the cladding layer has a higher electrical conductivity in the intermediate region than in the first facet region.
